(19) United States
(12) Patent Application Publication
(10) Pub. No.: US 2022/0037577 A1
(43) Pub. Date: Feb. 3, 2022

(54) MULTI-SHOWERHEAD CHEMICAL VAPOR DEPOSITION REACTOR, PROCESS AND PRODUCTS

(71) Applicant: Corning Incorporated, Corning, NY (US)

(72) Inventor: Rajaram Bhat, Burlington, NC (US)

(21) Appl. No.: 17/430,872

(22) PCT Filed: Feb. 25, 2020
(86) PCT No.: PCT/US2020/019632

§ 371 Date: Aug. 13, 2021

Related U.S. Application Data
(60) Provisional application No. 62/809,986, filed on Feb. 25, 2019.

(51) Int. Cl. H01L 39/24; C23C 16/455; C23C 16/02; C23C 16/48; C23C 16/54

(52) U.S. Cl. CPC H01L 39/2441; C23C 16/45565; C23C 16/545; C23C 16/0209; C23C 16/48; C23C 16/45519

(57) ABSTRACT

A method of forming a kilometer(s)-length high temperature superconductor tape by feeding a textured tape from roll-to-roll through a reactor chamber, flowing high temperature superconductor precursors from an elongated precursor showerhead positioned in the chamber the elongation in a direction along the tape; flowing gas from first and second elongated gas curtain shower heads on either side of the precursor showerhead; and illuminating the upper surface of the tape with illumination from sources on opposing sides of the reactor, the illumination sources positioned so as to allow illumination to pass under a respective one of the curtain shower heads and under the precursor showerhead to the upper surface of the tape.

This application claims the benefit of priority under 35 U.S.C. § 119 of U.S. Provisional Application No. 62/809,986, filed Feb. 25, 2019, the content of which is incorporated herein by reference in its entirety.

### FIELD OF THE DISCLOSURE

The disclosure relates to multi-showerhead metal organic chemical vapor deposition (MOCVD) reactors having multiple shower heads, particularly useful for manufacture of high temperature superconductor (HTS) tapes or wires, and to processes for manufacturing HTS tapes or wires, and to HTS tapes or wires producible using the disclosed reactor and/or method.

### BACKGROUND

Second generation high temperature superconductor (HTS) tapes or wires consist of a rare-earth-barium-copper oxide (REBCO) layer deposited on a textured metal tape (typically Hastelloy or stainless steel). These have been deposited by physical vapor deposition techniques such as pulsed laser deposition (PLD) and reactive co-evaporation (RCE), by a solution technique such as metal organic deposition (MOD) and by metal organic chemical vapor deposition (MOCVD). For successful commercial use, kilometer-scale lengths of HTS tapes with uniform properties—and at costs comparable to copper cables of similar current carrying capacity—are needed. To date, no manufacturing equipment or process has been sufficiently successful to meet this need.

Use of photoexcited MOCVD has been proposed to improve the crystal quality of the REBCO layer and hence improve performance of the HTS tape. In addition, it has been suggested that photoexcitation may enable increasing the growth rate while maintaining good performance. However, there has been no process or reactor design in which photoexcitation can be used to produce kilometer lengths of HTS tape. In addition, or in the alternative, no reactor with photoexcitation has been demonstrated where high growth rates, uniform deposition and high reactor efficiency can be obtained over a large deposition zone—such as a 10 cm×100 cm deposition zone, for example. It would thus be desirable to establish a process and/or a reactor in which photoexcitation can be used to produce kilometer lengths of HTS tape and/or in which uniform deposition and high reactor efficiency can be obtained over a large deposition zone. Particularly if these properties can be achieved together in a process and/or reactor, it is believed that successful commercial production of HTS tapes can be achieved in that kilometer-length HTS tapes or wires can be produced with good quality and at reasonable cost.

### SUMMARY OF THE DISCLOSURE

According to some aspects of the present disclosure, a multiple showerhead chemical vapor deposition reactor is provided. The reactor comprises a reactor chamber enclosed by a chamber wall, the chamber having a length and a width, the length being greater than the width. The chamber wall has entry and exit seal ports at opposite ends of the chamber in the length direction for receiving and delivering a tape during deposition on said tape. The chamber contains a support plate for supporting said tape. The support plate has a length and a width, the length being greater than the width.

A precursor showerhead is positioned within the chamber, and has a length and a width, the length being greater than the width. The precursor showerhead positioned over the support plate with the length dimension of the precursor showerhead parallel to the length dimension of the support plate. First and second gas curtain shower heads are positioned within the chamber on either side of the precursor showerhead. The first and second gas curtain shower heads each have a length and a width with the length being longer than the width. The gas curtain showerheads are positioned with the length dimensions of the gas curtain showerheads aligned parallel to the length dimension of the precursor showerhead.

The reactor further comprises one or more first illumination sources positioned on a first side of the width of the chamber and one or more second illumination sources positioned on a second side of the width of the chamber. The illumination sources are so positioned and aligned as to be capable to illuminating an upper surface of said tape during deposition, by shining a beam of illumination under the respective gas curtain shower head and under the precursor showerhead to said upper surface.

According to other aspects of the present disclosure, a method of forming a kilometer(s)-length high temperature superconductor tape is provided. The method comprises feeding a textured tape from a feed roll, through a reactor chamber having a chamber wall, to a take-up roll; flowing high temperature superconductor precursors from an elongated precursor showerhead positioned in the chamber facing an upper surface of the tape, the precursor showerhead elongated in a direction along a centerline of the tape; flowing gas from first and second elongated gas curtain shower heads positioned in the chamber on either side of the precursor showerhead, the first and second elongated gas curtain shower heads elongated in a direction parallel to the centerline of the tape; and illuminating the upper surface of the tape with illumination from one or more first and one or more second illumination sources on opposing sides of the reactor, the illumination sources positioned so as to allow illumination to pass under a respective one of the curtain shower heads, and under the precursor showerhead, to the upper surface of the tape.

Additional features and advantages will be set forth in the detailed description which follows, and will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the disclosure and the appended claims.

The accompanying drawings are included to provide a further understanding of principles of the disclosure, and are incorporated in, and constitute a part of, this specification. The drawings illustrate one or more embodiment(s) and, together with the description, serve to explain, by way of example, principles and operation of the disclosure. It is to be understood that various features of the disclosure disclosed in this specification and in the drawings can be used in any and all combinations. By way of non-limiting examples, the various features of the disclosure may be combined with one another according to the following embodiments.

### BRIEF DESCRIPTION OF THE DRAWINGS

The following is a brief description of the figures in the accompanying drawings. The figures are not necessarily to scale, and certain features and certain views of the figures may be shown exaggerated in scale or in schematic in the interest of clarity and conciseness.

In the drawings:

FIG. 1 is a cross-sectional plan view of a reactor according to at least one example of the disclosure;

FIG. 2 is a schematic view of a cross section taken along the line II-II indicated in FIG. 1, showing one or more of one or more alternative embodiments, such as alternate or optional features of the present disclosure;

FIG. 3 is a cross-sectional schematic view taken along the line III-III indicated in FIG. 1, according to one or more embodiments of the disclosure; and

FIG. 4 is a cross-sectional schematic view corresponding to that of FIG. 3, showing a further one or more features of one or more alternative embodiments.

### DETAILED DESCRIPTION OF THE PREFERRED EMBODIMENTS

Additional features and advantages will be set forth in the detailed description which follows and will be apparent to those skilled in the art from the description, or recognized by practicing the embodiments as described in the following description, together with the claims and appended drawings.

As used herein, the term “and/or,” when used in a list of two or more items, means that any one of the listed items can be employed by itself, or any combination of two or more of the listed items can be employed. For example, if a composition is described as containing components A, B, and/or C, the composition can contain A alone; B alone; C alone; A and B in combination; A and C in combination; B and C in combination; or A, B, and C in combination.

In this document, relational terms, such as first and second, top and bottom, and the like, are used solely to distinguish one entity or action from another entity or action, without necessarily requiring or implying any actual such relationship or order between such entities or actions.

Modifications of the disclosure will occur to those skilled in the art and to those who make or use the disclosure. Therefore, it is understood that the embodiments shown in the drawings and described above are merely for illustrative purposes and not intended to limit the scope of the disclosure, which is defined by the following claims, as interpreted according to the principles of patent law, including the doctrine of equivalents.

For purposes of this disclosure, the term “coupled” (in all of its forms: couple, coupling, coupled, etc.) generally means the joining of two components directly or indirectly to one another. Such joining may be stationary in nature or movable in nature. Such joining may be achieved with the two components and any additional intermediate members being integrally formed as a single unitary body with one another or with the two components. Such joining may be permanent in nature, or may be removable or releasable in nature, unless otherwise stated.

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. When the term “about” is used in describing a value or an end-point of a range, the disclosure should be understood to include the specific value or end-point referred to. Whether or not a numerical value or end-point of a range in the specification recites “about,” the numerical value or end-point of a range is intended to include two embodiments: one modified by “about,” and one not modified by “about.” It will be further understood that the end-points of each of the ranges are significant both in relation to the other end-point, and independently of the other end-point.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, “substantially” is intended to denote that two values are equal or approximately equal. In some embodiments, “substantially” may denote values within about 10% of each other, such as within about 5% of each other, or within about 2% of each other.

Directional terms as used herein—for example up, down, right, left, front, back, top, bottom—are made only with reference to the figures as drawn and are not intended to imply absolute orientation.

As used herein the terms “the,” “a,” or “an,” mean “at least one,” and should not be limited to “only one” unless explicitly indicated to the contrary. Thus, for example, reference to “a component” includes embodiments having two or more such components unless the context clearly indicates otherwise.

A number of deposition methods for depositing YBCO layers on metal tapes exist.

These include pulsed laser deposition (PLD), reactive co-evaporation (RCE), metal organic deposition (MOD) and metal organic chemical vapor deposition (MOCVD). MOCVD has been used to deposit YBCO on metal tapes in a reel-to-reel process. The tapes are 12 mm wide and are passed multiple times to obtain a sufficiently thick layer in a reasonable time. Multiple passes are used because the deposition rate is low. At higher deposition rates the crystalline quality deteriorates and the desired performance (critical current, critical temperature, magnetic field performance, etc.) cannot be obtained. Photo-excitation assisted deposition has been used to achieve good quality layers at higher deposition rates, but poor utilization of the metal organic precursors and a poor uniformity of YBCO thickness have been encountered.

In general, the disclosure is directed to a metal organic chemical vapor deposition (MOCVD) reactor having multiple shower heads which is particularly suited for manufacture of high temperature superconductor (HTS) tapes or wires, and to processes for manufacturing HTS tapes or wires.

Disclosed is a reactor that enables the reel-to-reel deposition of high temperature superconductor layers, such as YBCO, on a kilometer-length textured metal tape, by photo-excited metal organic chemical vapor deposition with consistent high quality. The reactor can operate over long periods of time without appreciable attenuation of the photo-excitation, enabling kilometer(s)-scale tapes or wires to be produced.

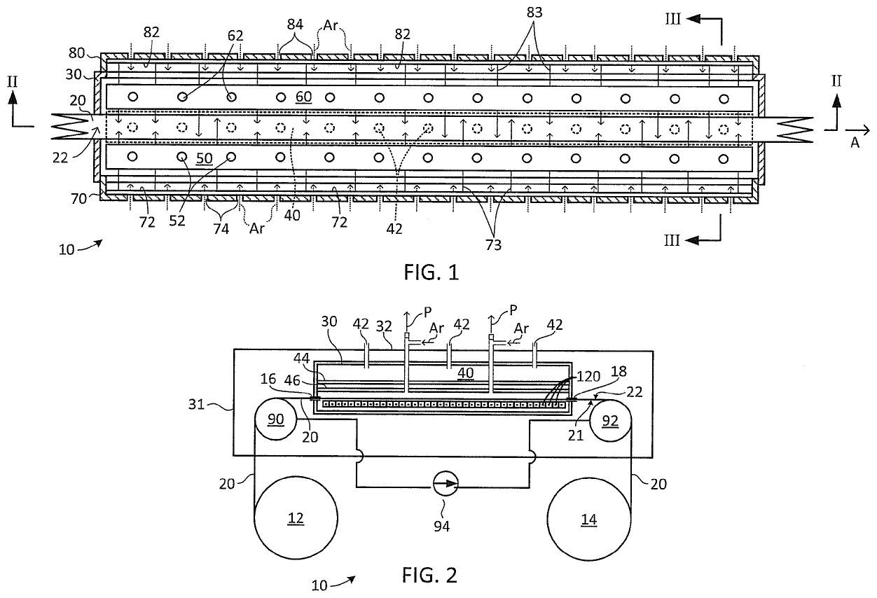

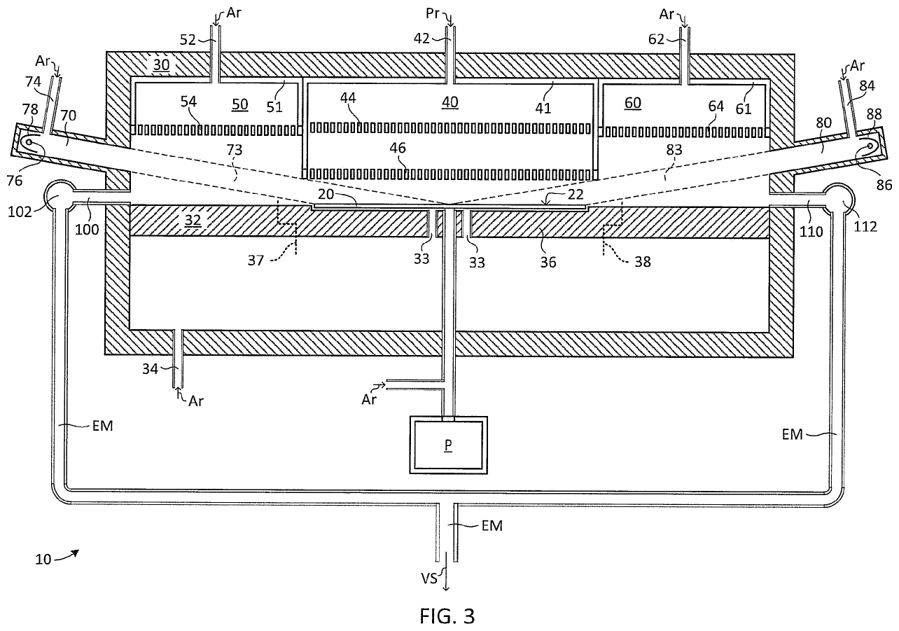

Referring to FIGS. 1 and 3, the reactor 10 comprises multiple showerheads 40, 50, 60, wherein a precursor showerhead 40, placed relatively closer to the location of an upper surface 22 of a textured metal tape 20 when being processed, provides a uniform flow of precursors over the upper surface 22 of the metal tape 20, and first and second gas curtain showerheads 50, 60 provide a gas curtain (an inert or otherwise non-reactive gas curtain) on either side of the precursor showerhead 40, on either side of the tape 20. The gas curtains assist in preventing deposition on a light or radiation source 72, 82 or alternatively on a window 71, 81 (through which the light or radiation source provides light or radiation on the upper surface of the textured metal tape 20. The light source(s) 72, 82 or windows 71, 81 can comprise quartz windows, for example, or light emitting diodes (LEDs) with optics, with the optics structured to enable transmitting all or much of the light from the LEDs through a narrow gap between the showerheads 40, 50, 60 and the tape 20 (particularly between the precursor showerhead 40 and the tape 20).

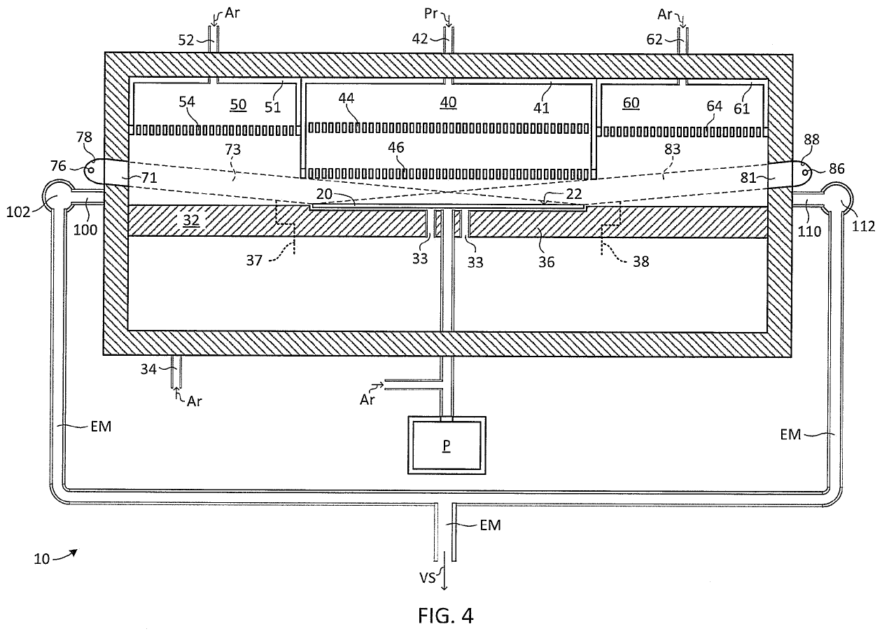

According to one embodiment, a first set 72 of light emitting diodes shines light on one half of the tape 20 and a second set 82 onto the other half, as indicated in FIG. 3, in which radiation from LEDs 76, 86, is reflected by mirrors 78, 88, to form respective beams 73, 83, (collimated or focused), each beam in effect illuminating one-half of the upper surface 22 of the tape 20. Alternatively, the reactor 10 and the beams 73, 83, as seen in FIGS. 1 and 4, may be structured such that the beams 73, 83 illuminate, from both sides, all or most of the upper surface 22 of the tape 20.

A heating mechanism such as channels (not shown) is provided to the reactor walls and other parts of the reactor to allow heating of the reactor parts and walls, such as by a flow of a heat transfer fluid, so as to maintain all reactor walls and internal part surfaces (except the LEDs or windows) at a high enough temperature to prevent condensation of precursors or reaction byproducts but not so high as to decompose them (for example, in the range of from 300 to 400° C., or about 350° C.).

With reference to FIG. 2, the tape 20 can be heated to the deposition temperature by passing current through it, such as passing current through the tape 20 between two conductive rollers 90, 92 contacting the tape 20 and connected to a constant current source 94. Alternatively, or in addition, tungsten-halogen lamps 120 which are positioned below the tape 20 facing the lower surface 21 of the tape 20 may be used to heat the tape 20. The reactor 10 may include an outer enclosure 31. The pressure in this outer enclosure 31, if present, is higher than in the reactor housing 30, with the pressure being maintained by differential pumping. The tape 20 enters and exits the reactor housing 30 through one or more differentially pumped entrance tubes and exit tubes 16, 18 (one of each shown). (Similarly, the tape 20 enters and exits the outer enclosure 31 through differentially pumped tubes, as depicted in one or more of the Figures.)

With reference again to FIGS. 1-3 with particular emphasis on features in FIG. 3, a tape or wire 20, desirably sized in width in the range of from at 0.1 to 20 cm, or 1 to 15 cm, or 5 to 15 cm, or 8 to 12 cm, moves out of the plane of the paper in FIG. 3, or to the right as shown by arrow A in FIG. 1, from a feed reel 12 to a take-up reel 14 as in FIG. 2. The reels 12, 14 can be at atmospheric pressure or at low vacuum (e.g. low vacuum). There can be several stages of differential pumping between the reactor 10 and the pressure at which the reels 12, 14 are maintained. For the embodiment of the reactor 10 shown in FIG. 3, the tape 20 is heated by passing an electrical current from a constant current source 94 as shown in FIG. 2 (i.e., without the optional or alternative lamps 120 also shown in FIG. 2).

Precursors in a carrier gas are fed at multiple points 42 along a deposition zone having a length in the range of from 25 to 1000 cm, or from 50 to 500 cm, or from 60 to 300, or from 70 to 250 cm, or from 80 to 150 cm or about 100 cm, by the close-spaced (and central) precursor showerhead 40. The precursor showerhead 40 is positioned close (1-2 cm) to the textured tape 20. The precursor showerhead 40 has two porous plates (placed serially in the gas flow, functioning as a mixing plate and a showerhead) so as to provide enough pressure differential and even distribution of the precursors over the upper surface of the tape 20. Two additional showerheads 50, 60 create an inert gas curtain that prevent precursors or reaction byproducts from reaching the LEDs or the window through which the LED light is brought into the reactor 10. In addition, the LEDs or the window is placed in a purged recess 80 to further inhibit any precursor or reaction byproducts from reaching the light source. An exhaust manifold on the two sides (shown in FIG. 3) is connected to a vacuum pump (not shown) that maintains the reactor at the desired pressure using a throttle valve. All reactor walls and internal part surfaces (except the LEDs) are kept at a high enough temperature (for example 350 C) to prevent condensation of precursors or reaction byproducts but not so high as to decompose them. The temperature of the tape 20 is monitored and controlled by one or more pyrometers that senses the bottom surface or the top surface of the tape (top surface monitoring shown in FIG. 2).

The precursor showerhead 40 produces a stagnant point flow to obtain uniform YBCO layers on a 10 cm wide metal (Hastelloy, stainless steel, etc) tape 20 while at the same time achieving high precursor utilization. The tape 20 could be narrower or wider, in which case a narrower or wider precursor showerhead 40 is needed. The length of the precursor showerhead 40 is desirably 100 cm long in this design but can be shorter or longer depending on the desired length of the deposition zone. Photo-excitation is desirably provided by light emitting diodes (LEDs) emitting at 385-405 nm (e.g. where the wavelength can be tailored to be shorter or longer) The beam of light from the LEDs on one side of the reactor is directed on to on half of the tape. Tape heating can be done bypassing a current through the tape or by tungsten-halogen lamps placed below the tape. A schematic of a reactor 10, where the tape 20 is heated by passing a current through it, is shown in FIG. 2.

As can be seen in FIGS. 1 and 3, deposition on the LEDs is greatly minimized, or even completely avoided, by having two curtain showerheads 50, 60, placed on either side of the precursor showerhead 40, to provide a gas curtain of inert or otherwise non-reactive gas. In addition, the windows or the LEDs and associated optics 72, 82 are placed in a gas-purged recess 80 to provide additional protection against precursors or reaction byproducts depositing on them. As shown for example in FIG. 2, according to one embodiment, the light sources 72, 82 may be arrays of LEDs 76, 86 with parabolic reflectors 76, 86 directing collimated light beams 73, 83 on to essentially one-half (a respective one-half) of the tape 20 all along the deposition zone. All reactor walls and showerheads are heated to about 350 C to prevent precursors or reaction byproducts depositing on them and thereby eliminating the need to clean the reactor after every run. This also greatly reduces the possibility of particles falling on the tape. The LEDs are desirably water cooled. In the embodiment in which light source 72, 82 are in the form of windows, it is also possible to have LEDs and optics outside the reactor chamber, with the light brought in through UV-transparent windows 72, 82. Using optics, the LED light beam is can desirably be made just sufficiently high to illuminate one half of the tape but it can optionally also be fanned out laterally to illuminate 5-10 cm length of the tape.

The tape temperature is monitored by an emissivity corrected pyrometer or by one or more such pyrometers P as indicated in FIGS. 2 and 3, directed on to the upper side (FIG. 2) or to the underside (FIG. 3) of the tape. The pyrometer port(s) is/are purged with gas to prevent any deposition of precursors or reaction byproducts on the pyrometer. An exhaust manifold EM is connected to the chamber 30 via exhaust ports 100, 110 on either side of the reactor 10 and to a suitable vacuum pump (location and direction of flow shown by arrow VP), which maintains the reactor 10 at the desired pressure. The spacing between the main showerhead and the tape is desirably about 1-2 cm, preferably about 1 cm. This relatively small spacing ensures that the Grashof number is low, as the Grashof number is proportional to the cube of the spacing. With a sufficiently low Grashof number, buoyancy induced convection is avoided. The resulting stagnant point flow geometry used ensures uniform deposition, as the boundary layer, and the concentration of precursors above the boundary layer, are constant across the width of the tape 20.

The tape 20 is desirably brought into the reactor through differentially pumped chamber/outer enclosure 31 (FIG. 2) so as to enable having feed and take-up reels 12, 14, at atmospheric pressure. Current is fed to and drawn from the tape through desirably water cooled, highly conductive cylindrical electrodes 90, 92. In some embodiments, the electrodes 90, 92 are configured in electrical isolation from ground and/or the rest of the reactor components/parts. The electrode surfaces are highly polished to ensure a good contact. The current is fed from a constant current source 94 so that any variations in contact resistance do not matter. The main or precursor showerhead 40 has two porous plates 44, 46, to ensure uniform flow from the showerhead 40. The outermost showerhead plate 46 has pores of about 0.6-1 mm (preferably 0.8 mm) diameter and they are about 0.5 to 1 cm long. The density of pores is 15-20 per square cm. The inner showerhead plate 44 can have pores that are 1-2 mm dia, 0.5 to 1 cm long and a density of 4 to 20 per square cm. The gas is fed to the main showerhead via a manifold (not shown) at multiple ports 42 along the showerhead 40 so as to distribute it evenly possible above the inner showerhead plate 44. The two outer or curtain showerheads 50, 60 that provide a gas curtain (desirably an inert gas or Ar gas curtain) have plates 54, 64 with pore sizes, lengths and densities similar to that of the inner showerhead plate 46 in the precursor showerhead 40. Gas, desirably Ar, is fed to these outer showerheads 50, 60 via a manifold (not shown) at multiple ports 52, 62 along the respective showerhead 50, 60 so as to distribute it evenly above the respective porous plate 54, 64. A plate 32 (support plate) separates the reactor chamber 30 into two parts. The spacing between the tape and the plate 32 (support plate) is desirably about 1 mm at the bottom of the tape 20 and at its edges. One or more slots or holes 33 in support plate 32 allows gas (inert purge gas) to be fed uniformly under the tape 20. This flow prevents any precursor or reaction byproducts from depositing on the underside of the tape 20 or entering the bottom part of the reaction chamber 30. In some embodiments, the support plate is configured in a spaced relation (e.g. non-contact) with the tape, and the support plate is configured to support one or more gas purge lines configured through the support plate and directed towards a lower-surface of the tape. In some embodiments, a tape is directly heated with an electric current (i.e. direct contact with support plate) or heated with halogen lamps (i.e. no direct-contact with a support plate). In the configuration where there is not direct contact, the support plate is configured to allow gas purging to be directed towards the back side of the tape. For embodiments with heating using a susceptor, the susceptor is also referred to as a support plate herein, and in this instances, the there can be additional thermally isolated “support plates” on either side of the susceptor/support plate. If the support plate was used as a support plate in the case of current heating, there would be an additional insulating material configured/placed at regular intervals along the length of the tape. Modeling has indicated that the deposition uniformity is about 1.7% and the reactor efficiency is about 40%.

The tape 20 can alternatively or additionally be heated using tungsten-halogen lamps 120 placed under the tape 20 as also shown in FIG. 2. A fused quartz window may be used in the mid-section of the plate 32 (such as the mid-section 36 delineated by the dashed lines 37, 38) to allow the lamp radiation to shine on the bottom surface of the tape 20. The one or more slots or holes 33 (spaced evenly along the deposition zone in the case of a plurality) allow purging of the space between the tape 20 and the quartz window. The inert purge gas prevents deposition on the quartz window by not allowing precursors and reaction byproducts to enter the space between the tape 20 and window.

A group of the lamps 120 are desirably controlled by one PID controller that gets feedback from an emissivity corrected pyrometer P which monitors the top or bottom surface of the tape 20. Emissivity corrected optical pyrometers are placed along the length of the deposition zone to provide feedback to the particular group of lamps that are below them. Multi-zone heating zones enables the temperature profile along the tape to be adjusted. The pyrometers P can be positioned so as to monitor the temperature of the top surface of the tape or the bottom surface. If the pyrometers monitor the top surface, narrow diameter purged ports that are sealed at one end with a fused quartz window are fabricated within the showerhead as shown in FIG. 2. If the pyrometers are placed below the tape to monitor the back surface of the tape (FIG. 3), the tip of the pyrometer tube should be far enough away from the tape so that there is no shadowing of the lamp's radiation. Also, the inner surface of the pyrometer tube should be rough so that reflected light cannot propagate down to the pyrometer by multiple reflections along the inner walls.

The tape can also be heated by an electrically heated susceptor (heater) placed in contact with the tape. The susceptor and the tape path will need to be curved to maintain good contact between the susceptor and the tape. In some embodiments, the radius of the curve is between about 20 to 50 m, preferably 25 m. In some embodiments, in order to maintain a constant height between the tape and the showerhead, the shower heads are also be curved

The tape may be heated using a combination of methods, such as Tungsten halogen lamps heating the tape from underneath and also heated by passage of electric current, as shown in FIG. 2.

Using either a linear array of transmissive glass cylindrical lenses or a linear reflective collimator, such as available from Chromasens (Konstanz Germany). Light from the linear array of LEDs can thus be collimated in one dimension to illuminate the entire length and width of the tape, such as seen in the illustration of the beams 73, 83 in FIG. 4 (for width) and in FIG. 1 (for length and width). This can be done by using LEDs on both sides of the chamber. The linear or (slightly) focused beams 73, 83 from either side of the chamber can (and desirably do) completely overlap, promoting good coverage and uniformity. A linear array of transmissive lenses is that the array of lenses or a single long strip cylindrical glass lens could also replace the transparent windows 71, 81 in the sides of the deposition chamber, as an additional alternative aspect.

One embodiment of a cylindrical lens that can work is a K&S Optics (Greene N.Y. USA) 100-200 cylindrical plano-convex lens made of N-BK7 with a focal distance of 10 mm and a diameter of 12.5 mm. The lens can be placed approximately 10 mm away from the LED to capture more than half the light from the LED and collimate it into a linear beam approximately 10 mm wide.

An alternative lens is one available from Thorlabs (Newton N.J. USA), the LJ1878L2-A, with similar focusing characteristics. The Thorlabs lens has one advantage, namely an antireflective coating for the 350 to 700 nm wavelength range that encompasses the wavelengths most of interest for the deposition chamber.

The linear reflective embodiment can use a reflector similar to the reflectors Type C or Type D from Chromasens, for example. Details of the specific form of the reflector can be tailored to the final form of the deposition chamber so the proper trade-off can be made between the uniformity and the efficiency of the light illumination.

The choice of metallic coating is important for the reflective elements. For wavelengths shorter than 500 nm, Aluminum is generally the low loss choice. At longer wavelengths, Silver and Gold are favored. If one material needs to be used across a wide range of wavelengths including wavelengths both above and below 500 nm, aluminum is generally preferred for its uniformly low loss.

The choice of LEDs wavelengths: It is possible to construct the arrays of LEDs with a diversity of wavelengths that are chosen to optimize the reaction and deposition processes. For this YCBO reactor, a series of wavelengths can be used from the UV into the visible. One embodiment has groups of 3 wavelength LEDs repeated along the length of the LED array with 365, 385 and 405 nm LEDs in the group to provide complete spectral coverage in the near UV and the shortest blue wavelength range. The same kind of wavelength diversity schemes can be made with other kinds of optical sources like lasers.

While exemplary embodiments and examples have been set forth for the purpose of illustration, the foregoing description is not intended in any way to limit the scope of disclosure and appended claims. Accordingly, variations and modifications may be made to the above-described embodiments and examples without departing substantially from the spirit and various principles of the disclosure. All such modifications and variations are intended to be included herein within the scope of this disclosure and protected by the following claims.

1. A multiple showerhead chemical vapor deposition reactor comprising:
a reactor chamber enclosed by a chamber wall, the chamber having a length and a width, the length being greater than the width, the chamber wall having entry and exit seal ports at opposite ends of the chamber in the length direction for receiving and delivering a tape during deposition on said tape;
a support plate within the chamber for supporting said tape, the support plate having a length and a width, the length being greater than the width;
a precursor showerhead positioned within the chamber, the precursor showerhead having a length and a width, the length being greater than the width, the precursor showerhead positioned over the support plate with the length dimension of the precursor showerhead parallel to the length dimension of the support plate;
first and second gas curtain shower heads positioned on either side of the precursor showerhead, the first and second gas curtain shower heads each having a length and a width, the length being longer than the width, the length dimensions of the gas curtain showerheads aligned parallel to the length dimension of the precursor showerhead;
one or more first illumination sources positioned on a first side of the width of the chamber and one or more second illumination sources positioned on a second side of the width of the chamber so positioned and aligned to be capable to illuminate an upper surface of said tape during deposition by shining a beam of illumination under the respective gas curtain shower head and under the precursor showerhead to said upper surface.

2. The reactor of claim 1, wherein the one or more first illumination sources are positioned within one or more first recesses in the first side of the chamber and the one or more second illumination sources are positioned within one or more second recesses in the second side of the chamber.

3. The reactor of claim 2, wherein the one or more first recesses and the one or more second recesses are provided with a respective gas port communicating with the interior of the respective recess.

4. The reactor of claim 1, wherein the support plate comprises one or more slots or ports positioned under said tape for delivering a purge gas flow between said tape and the support plate.

5. The reactor of claim 1, wherein the precursor showerhead is wider than 10 mm.

6. The reactor of claim 1, wherein the precursor showerhead is positioned closer to a plane coincident with said upper surface than are the gas curtain showerheads.

7. The reactor of claim 1, wherein the precursor showerhead is positioned within 0.8 to 2 cm from said upper surface.

8. The reactor of claim 1, wherein the precursor showerhead is positioned within 0.8 to 1.2 cm from said upper surface.

9. The reactor of claim 1, wherein the precursor showerhead comprises one or more porous mixer-distributor plates.

10. The reactor of claim 9, wherein the precursor showerhead comprises at least two porous mixer-distributor plates, including a first mixer-distributor plate having a first pore size and a second mixer-distributor plate having a second pore size, the second mixer-distributor plate positioned between the first mixer-distributor plate and the support plate, the first pore size being larger than the second pore size.

11. The reactor of claim 1, further comprising first and second conductive platens or rollers positioned to contact said tape to provide for heating said tape by passing a current along said tape

12. The reactor of claim 11 further comprising a constant current source connected to the first and second conductive platens or rollers.

13. The reactor of claim 1, further comprising radiation sources positioned below the support table for heating said tape.

14. The reactor of claim 1, further comprising one or more temperature sensors positioned to sense a temperature of said tape.

15. The reactor of claim 14, wherein the one or more temperature sensors comprises one or more pyrometers positioned facing said upper surface.

16. The reactor of claim 14, wherein the one or more temperature sensors comprises one or more pyrometers positioned facing a lower surface of said tape.

17. Method of forming a kilometer(s)-length high temperature superconductor tape, the method comprising:
feeding a textured tape from a feed roll, through a reactor chamber having a chamber wall, to a take-up roll;
flowing high temperature superconductor precursors from an elongated precursor showerhead positioned in the chamber facing an upper surface of the tape, the precursor showerhead elongated in a direction along a centerline of the tape;
flowing gas from first and second elongated gas curtain shower heads positioned in the chamber on either side of the precursor showerhead, the first and second elongated gas curtain shower heads elongated in a direction parallel to the centerline of the tape;
illuminating the upper surface of the tape with illumination from one or more first and one or more second illumination sources the illumination sources positioned so as to allow illumination to pass under a respective one of the curtain shower heads, and under the precursor showerhead, to the upper surface of the tape.

18. The method of claim 17, wherein feeding the tape is continuously feeding the tape.
